(19) United States
(12) Patent Application Publication
(10) Pub. No.: US 2022/0372613 A1
(43) Pub. Date: Nov. 24, 2022

(54) SUBSTRATE FIXING DEVICE FOR SCINTILLATOR DEPOSITION, SUBSTRATE DEPOSITION APPARATUS INCLUDING THE SAME, AND METHOD OF DEPOSITING A SCINTILLATOR USING THE SAME

(71) Applicant: VIEWORKS CO., LTD., Anyang-si, Gyeonggi-do (KR)

(72) Inventor: In Hyuck RYU, Osan-si, Gyeonggi-do (KR)

(73) Assignee: VIEWORKS CO., LTD., Anyang-si, Gyeonggi-do (KR)

(21) Appl. No.: 17/764,106

(22) PCT Filed: Sep. 23, 2020
(86) PCT No.: PCT/KR2020/012896

§ 371 Date: Mar. 25, 2022

(30) Foreign Application Priority Data
Sep. 27, 2019 (KR) 10-2019-0119518
Sep. 18, 2020 (KR) 10-2020-0120546

(51) Int. Cl. C23C 14/50; C23C 14/24; C23C 14/54; C23C 14/56

(52) U.S. Cl. CPC C23C 14/505; C23C 14/24; C23C 14/541; C23C 14/56

(57) ABSTRACT

A substrate fixing device according to the present invention is a substrate fixing device configured to fix a substrate so that a deposition material evaporated from at least one evaporation source is deposited on the substrate. The substrate fixing device includes a substrate temperature adjustment part configured to transfer heat to the substrate, and a substrate fixing part coupled to one side of the substrate temperature adjustment part and configured to fix the substrate, in which the substrate fixing part fixes the substrate so that a front surface of the substrate is exposed in a direction toward the evaporation source, and in which a space is formed between the substrate fixing part and a rear surface of the substrate.

### TECHNICAL FIELD

The present invention relates to a substrate fixing device for scintillator deposition, a substrate deposition apparatus including the same, and a method of depositing a scintillator using the same, and more particularly, to a substrate fixing device to which backside cooling is applied, a substrate deposition apparatus including the same and a method of depositing a scintillator using the same.

### BACKGROUND ART

As devices used for radiography for medical image diagnosis or non-destructive testing, there are an X-ray detector that detects image signals by converting emitted X-rays directly into electrical signals, and a flat panel detector (FPD) that adopts an indirect conversion method that converts radioactive rays, which have passed through a subject, into light by using a scintillator and detects the light, which is converted and discharged from the scintillator, by a light-receiving element.

As the scintillator, a group of columnar crystals of compounds of alkaline metal compound halides such as cesium iodide and thallium iodide is widely used to efficiently transmit the light emitted from the scintillator to the light-receiving element of the X-ray detector.

In the group of columnar crystals formed on the scintillator, pores are formed between the respective columnar crystals. Because of a difference in refractive index between the columnar crystal and gas, the light may be totally reflected repeatedly in the crystal, and the emitted light may be guided to the light-receiving element of the X-ray detector.

During a process of depositing the scintillator, a part of a scintillator deposition device may be accommodated in a chamber in a vacuum state, and a deposition material may be deposited on a substrate fixed to the scintillator deposition device in the chamber.

Backside cooling refers to a method that supplies gas into a space between a substrate fixing part configured to fix a substrate and a rear surface of the substrate on which a deposition material is deposited during the process of depositing the scintillator, and adjusts heat transferred to the substrate by convection by means of the supplied gas. The backside cooling enables a process of precisely controlling a temperature of the heat to be transferred to the substrate in the chamber in a vacuum state without affecting a front surface of the substrate on which the deposition process is performed.

Meanwhile, as a configuration for controlling a temperature of a heater provided in the scintillator deposition device used for the process of depositing the scintillator in the related art, there is a configuration only having a heating function or a configuration that cannot finely control the temperature.

### DISCLOSURE

### Technical Problem

An object of the present invention is to provide a substrate deposition apparatus and a method of depositing a scintillator using the same, which deposit a scintillator on a substrate by applying backside cooling.

Another object of the present invention is to provide a substrate fixing device and a substrate deposition apparatus including the same, which are capable of precisely controlling a temperature of a substrate temperature adjustment part configured to transfer heat to a substrate at the time of applying backside cooling.

Still another object of the present invention is to provide a substrate deposition apparatus capable of easily adjusting a relative position and a direction of a substrate on which a deposition material is deposited during a process of depositing a scintillator.

### Technical Solution

An embodiment of the present invention provides a substrate fixing device, which is configured to fix a substrate so that a deposition material evaporated from at least one evaporation source is deposited on the substrate, the substrate fixing device including: a substrate temperature adjustment part configured to transfer heat to the substrate; and a substrate fixing part coupled to one side of the substrate temperature adjustment part and configured to fix the substrate, in which the substrate fixing part fixes the substrate so that a front surface of the substrate is exposed in a direction toward the evaporation source, and in which a space is formed between the substrate fixing part and a rear surface of the substrate.

In particular, the substrate temperature adjustment part may include: a first substrate temperature adjustment unit; an oil flow unit provided in the first substrate temperature adjustment unit and including a flow path in which oil introduced from an oil supply source circulates; and a second substrate temperature adjustment unit coupled to one side of the first substrate temperature adjustment unit.

In particular, the flow path may include an oil inflow line into which the oil is introduced; and an oil outflow line from which the oil is discharged, and the oil inflow line and the oil outflow line may be disposed to intersect each other.

In particular, the substrate fixing part may include: a first fixing unit having one side to which the second substrate temperature adjustment unit is coupled; and a second fixing unit coupled to the other side of the first fixing unit and formed such that the front surface of the substrate is exposed.

In particular, the substrate may be fixed between the first fixing unit and the second fixing unit.

In particular, the first fixing unit may include: a groove portion formed along an inner periphery of the first fixing unit; a sealing member accommodation portion spaced apart from the groove portion at a predetermined interval, disposed inside the groove portion, formed along the inner periphery of the first fixing unit, and configured to accommodate at least one sealing member; at least one guide pin formed between the groove portion and the sealing member accommodation portion and configured to guide the substrate when the substrate is seated on the first fixing unit; a gas supply hole through which gas is injected into the space; and a gas discharge hole through which the gas is discharged from the space.

In particular, the sealing member may seal a gap between the substrate and the first fixing unit and be in surface contact with the substrate.

In particular, an edge portion may be defined on the substrate and have a predetermined area along an outer edge portion of the substrate, and the edge portion may be disposed between the second fixing unit and the sealing member and configured to apply stress to the sealing member.

In particular, the second fixing unit may include: a rim portion formed on an inner peripheral surface of the second fixing unit; and a mask area formed at an end of the rim portion, and the mask area may be formed to be inclined with respect to a lower surface of the rim portion in a direction toward a central portion of the second fixing unit.

In particular, a total sum of weights of the first and second fixing units may be kept constant.

In particular, the substrate fixing device may be coupled to a rotation shaft of a rotation part partially accommodated in a chamber having the evaporation source therein, and the substrate fixing device may rotate in conjunction with a rotation of the rotation shaft.

In particular, the evaporation source may be disposed at a lower end in the chamber, and the substrate fixing device may be positioned above the evaporation source.

Another embodiment of the present invention provides a substrate deposition apparatus, which is configured to deposit a deposition material evaporated from at least one evaporation source on a substrate, the substrate deposition apparatus including: a chamber configured to accommodate the evaporation source therein; a revolution part partially accommodated in the chamber and configured to rotate about a revolution shaft; a plurality of rotation parts coupled to the revolution part and configured to revolve in conjunction with a rotation of the revolution part; and the substrate fixing device, in which the substrate fixing device is coupled to a rotation shaft provided in the rotation part and configured to rotate.

In particular, a gas inflow/outflow control part may be connected to the chamber and a substrate fixing part provided in the substrate fixing device, and a space may be formed between the substrate fixing part and a rear surface of the substrate.

In particular, after the space and the chamber are formed in a vacuum state, the gas inflow/outflow control part may inject gas into the space while adjusting a pressure of the gas so that a predetermined pressure is maintained in the space during a deposition process.

In particular, the gas inflow/outflow control part may include: a pump configured to perform pumping on the space at a predetermined pumping speed; a gas supply source configured to accommodate gas to be supplied into the space; and a pressure controller connected to the gas supply source and configured to adjust a pressure of the gas to be supplied into the space.

In particular, in a state in which the pump performs pumping on the space at a predetermined pumping speed, the pressure controller may adjust a pressure of the gas to be supplied into the space by reading out a value of a pressure in the space.

In particular, the gas inflow/outflow control part may further include: a first valve disposed between the chamber and the space; a second valve disposed between the chamber and the pump; a third valve disposed between the pump and the space; and a fourth valve disposed between the space and the pressure controller.

In particular, the first valve and the second valve may be opened when the space and the chamber are formed in a vacuum state.

In particular, during the deposition process, the first valve and the second valve may be closed, and the third valve and the fourth valve may be opened.

In addition, the gas accommodated in the gas supply source may be inert gas.

In particular, the revolution part may include a revolution part frame to which the plurality of rotation parts is coupled, the revolution shaft may be coupled to a central portion of the revolution part frame, and the revolution part frame may rotate in conjunction with a rotation of the revolution shaft.

In particular, the rotation part may be coupled to the revolution part frame by means of a tilting shaft, and the rotation part independently and axially may rotate about the tilting shaft relative to the revolution part frame.

In particular, the evaporation source may be disposed at a lower end in the chamber, and the substrate fixing device may be positioned above the evaporation source.

Still another embodiment of the present invention provides a method of depositing a deposition material by using the substrate deposition apparatus, the method including: fixing a substrate to a substrate fixing part provided in the substrate deposition apparatus; connecting a space and an internal space of the chamber; forming the space and the internal space the chamber in a vacuum state; separating the space and the internal space of the chamber; supplying gas into the space; heating the substrate by controlling a temperature of a substrate temperature adjustment part coupled to the substrate fixing part; and depositing the deposition material evaporated from a plurality of evaporation sources on the substrate.

In particular, the method may further include performing pumping on the space at a predetermined pumping speed in the state in which the space and the internal space of the chamber are separated from each other.

In particular, the supplying of the gas into the space may include adjusting a pressure of the gas to be supplied into the space by reading out a value of a pressure in the space.

### Advantageous Effects

According to the embodiment of the present invention, the inside of the chamber and the space are separated from each other by using the gas inflow/outflow control part, and then the gas is injected into the space by performing pumping on the space at a predetermined pumping speed. Therefore, it is possible to constantly maintain the pressure of the gas supplied into the space during the process of depositing the scintillator.

In addition, the chamber and the space are formed in the vacuum state in the state in which the inside of the chamber and the space are connected to each other by using the gas inflow/outflow control part. Therefore, it is possible to prevent damage to the substrate caused by the difference in pressure between the space and the inside of the chamber.

In addition, according to the embodiment of the present invention, the sealing member is in surface contact with the substrate, such that the substrate may be easily detached from the substrate fixing part, and it is possible to prevent damage to the substrate caused when the substrate is bent.

In addition, according to the embodiment of the present invention, the oil is used as a heat transfer medium, which makes it possible to precisely control the temperature of the substrate temperature adjustment part configured to transfer heat to the substrate.

In addition, the substrate deposition apparatus including the plurality of rotation parts coupled to the revolution part may easily adjust relative positions and directions of the substrates with respect to the evaporation source by revolving the revolution part and tilting and rotating the rotation parts, thereby maximizing deposition efficiency.

### DESCRIPTION OF DRAWINGS

FIG. 1 is a conceptual view illustrating a substrate deposition apparatus according to an embodiment of the present invention.

FIG. 2 is a conceptual view illustrating a substrate deposition apparatus according to another embodiment of the present invention.

FIG. 3 is a view illustrating a substrate temperature adjustment part provided in the substrate deposition apparatus according to the present invention.

FIG. 4 is a view illustrating a flow path provided on the substrate temperature adjustment part according to the present invention.

FIG. 5 is a view illustrating an overall shape of a substrate fixing part provided in the substrate deposition apparatus according to the present invention.

FIG. 6 is a cross-sectional side view illustrating a substrate fixing part according to the present invention.

FIG. 7 is a view illustrating a first fixing unit of the substrate fixing part according to the present invention.

FIG. 8 is an enlarged view of part B in FIG. 6.

FIG. 9 is a view illustrating an edge portion formed on a substrate according to the present invention.

FIG. 10 is a view illustrating a space formed between the first fixing unit and the substrate according to the present invention (an enlarged view of part C in FIG. 6).

FIG. 11 is an enlarged view of a part of a second fixing unit of the substrate fixing part according to the present invention (an enlarged view of part D in FIG. 6).

FIG. 12 is a view illustrating a configuration of a gas inflow/outflow control part provided in the substrate deposition apparatus according to the present invention.

FIG. 13 is a flowchart illustrating a method of depositing a deposition material by using the substrate deposition apparatus according to the present invention.

### MODE FOR INVENTION

Hereinafter, exemplary embodiments of the present invention will be described in detail with reference to the accompanying drawings. First, in assigning reference numerals to constituent elements of the respective drawings, it should be noted that the same constituent elements will be designated by the same reference numerals, if possible, even though the constituent elements are illustrated in different drawings. In addition, in the description of the present invention, the specific descriptions of publicly known related configurations or functions will be omitted when it is determined that the specific descriptions may obscure the subject matter of the present invention. Further, the exemplary embodiments of the present invention will be described below, but the technical spirit of the present invention is not limited thereto and may of course be modified and variously carried out by those skilled in the art.

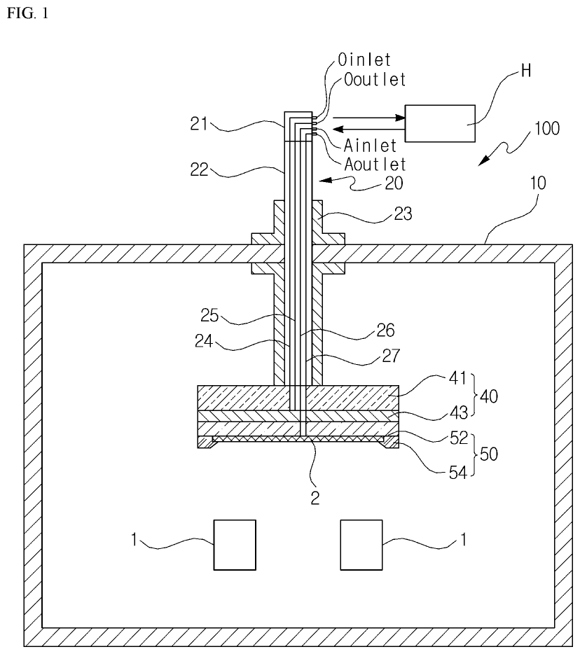

FIG. 1 is a conceptual view illustrating a substrate deposition apparatus 100 according to an embodiment of the present invention.

Referring to FIG. 1, a substrate deposition apparatus 100 according to the embodiment of the present invention includes a chamber 10 having therein a sealed space, a rotation part 20 connected to a rotation motor (not illustrated) and configured to be rotated by power transmitted from the rotation motor, a substrate temperature adjustment part 40 rotatably coupled to the rotation part 20 and configured to transfer heat to a substrate 2, and a substrate fixing part 50 coupled to one side of the substrate temperature adjustment part 40 and configured to rotate together with the substrate temperature adjustment part 40 and fix the substrate 2. In this case, the rotation motor may be disposed outside the chamber 10.

Hereinafter, in the present invention, a configuration including the substrate temperature adjustment part 40 and the substrate fixing part 50 is defined as a “substrate fixing device”.

Although not illustrated in FIG. 1, a gas inflow/outflow control part, will be described below, may be connected to the chamber 10 and the substrate fixing part 50 and make a vacuum in an interior of the chamber 10 and a vacuum between the substrate fixing part 50 and a rear surface of the substrate 2 or maintain a predetermined pressure in a portion between the substrate fixing part 50 and the rear surface of the substrate 2. The gas inflow/outflow control part may be connected to a gas discharge port (not illustrated) formed in a sidewall or an upper wall of the chamber 10.

The rotation part 20 includes a rotation shaft 22 connected to the rotation motor and configured to be rotated by power transmitted from the rotation motor. The rotation shaft 22 may penetrate the upper wall of the chamber 10 and be partially accommodated in the chamber 10. For example, the rotation shaft 22 may have a cylindrical shape, and particularly, be made of aluminum (Al), copper (Cu), iron (Fe), or other metal alloys.

In this case, the substrate temperature adjustment part 40 may be coupled to one end of the rotation shaft 22, the substrate fixing part 50 may be coupled to one side of the substrate temperature adjustment part 40, and the substrate temperature adjustment part 40 and the substrate fixing part 50 may rotate in conjunction with a rotation of the rotation shaft 22.

In addition, the rotation part 20 further includes a rotary joint 21 disposed at an upper side of the rotation shaft 22, and a sealing unit 23 disposed to be in close contact with an outer surface of the chamber 10 and configured to surround the rotation shaft 22.

The rotary joint 21 may be connected to an oil supply source (not illustrated) and a gas supply source to be described below. In addition, a heat exchanger H may be connected to the rotary joint 21 and exchange heat with oil that circulates in the substrate temperature adjustment part 40.

The rotary joint 21 includes an oil inlet Oᵢₙₗₑₜ, an oil outlet Oₒᵤₜₗₑₜ, a gas inlet Aᵢₙₗₑₜ, and a gas outlet Aₒᵤₜₗₑₜ.

The oil inlet Oᵢₙₗₑₜ and the oil outlet Oₒᵤₜₗₑₜ may be connected to the oil supply source, and the gas inlet Aᵢₙₗₑₜ and the gas outlet Aₒᵤₜₗₑₜ may be connected to the gas supply source.

In this case, the rotary joint 21 may be formed such that a bracket (not illustrated) of the rotary joint 21 coupled to the rotation shaft 22 is matched with the rotation shaft 22 to prevent a reduction in lifespan of the rotation shaft 22 due to assembly tolerance between the rotary joint 21 and the rotation shaft 22.

An oil inflow path 24 and an oil outflow path 25 may be formed in the rotation shaft 22 and connected to the oil inlet Oᵢₙₗₑₜ and the oil outlet Oₒᵤₜₗₑₜ, respectively. In addition, a gas inflow path 26 and a gas outflow path 27 may be formed in the rotation shaft 22 and connected to the gas inlet Aᵢₙₗₑₜ and the gas outlet Aₒᵤₜₗₑₜ, respectively.

The oil, which is supplied from the oil supply source through the oil inlet Oᵢₙₗₑₜ, may flow into the substrate temperature adjustment part 40 via the oil inflow path 24. The oil, which circulates in the substrate temperature adjustment part 40, may flow from the substrate temperature adjustment part 40 through the oil outflow path 25 and return back to the oil supply source through the oil outlet Oₒᵤₜₗₑₜ.

The gas, which is supplied from the gas supply source through the gas inlet Aᵢₙₗₑₜ, may flow into the substrate fixing part 50 via the gas inflow path 26. The gas may flow from the substrate fixing part 50 through the gas outflow path 27 and be discharged to the outside of the substrate deposition apparatus 10 through the gas outlet Aₒᵤₜₗₑₜ.

In this case, so that the oil inflow path 24 and the oil outflow path 25 may stably supply or discharge the oil to or from a flow path provided in the substrate temperature adjustment part 40 while passing through the inside of the rotation shaft 22, an oil inlet hole of the flow path and the oil inflow path 24 may have the same diameter, and an oil outlet hole of the flow path and the oil outflow path 25 may have the same diameter.

In addition, the gas inflow path 26 and a gas supply hole formed in the substrate fixing part 50 may have the same diameter, and the gas outflow path 27 and a gas discharge hole formed in the substrate fixing part 50 may have the same diameter, such that the gas inflow path 26 and the gas outflow path 27 may stably supply the gas into the substrate fixing part 50 while passing through the inside of the rotation shaft and the substrate temperature adjustment part 40 and may stably discharge the gas from the inside of the substrate fixing part 50.

Meanwhile, although not illustrated, in the present invention, a thermal insulator (not illustrated) may surround the oil inflow path 24, the oil outflow path 25, the gas inflow path 26, and the gas outflow path 27 to prevent heat in the respective paths from being discharged to the outside during the process of depositing the scintillator. In addition, the respective paths may be spaced apart from one another.

The sealing unit 23 may be made of a magnetic fluid (ferrofluid) having fluidity. In this case, the sealing unit 23 may eliminate heat transferred from the substrate temperature adjustment part 40 to a portion of the rotation shaft 22 positioned outside the deposition chamber 20.

In the present invention, a method using purified cooling water (PCW) may be used as a method of cooling the rotation shaft 22. In addition, the sealing unit 23 may be disposed on a boundary between an outside atmosphere and the chamber 10 kept in a vacuum state, i.e., to be close contact with an outer surface of the chamber 10 and to surround the rotation shaft 22. The sealing unit 23 may prevent a gas from flowing into the chamber 10 through a gap between the rotation shaft 22 and the chamber 10 during the deposition process. Therefore, the vacuum state in the chamber 10 may be maintained during the deposition process.

In addition, the substrate temperature adjustment part 40 is coupled directly to the rotation shaft 22 as described above, such that the heat generated by the substrate temperature adjustment part 40 may be transferred to the rotation shaft 22.

In this case, if the rotation shaft 22 and the substrate temperature adjustment part 40 are made of different materials, the rotation shaft 22 and the substrate temperature adjustment part 40 are different in coefficient of thermal expansion and the like, which may damage the rotation shaft 22. Therefore, the rotation shaft 22 and the substrate temperature adjustment part 40 may be made of the same material.

The substrate deposition apparatus 100, which has been described with reference to FIG. 1, may have the rotation part 20 including the single rotation shaft 22 and allow the rotation part 20 to be partially accommodated in the chamber 10.

In the substrate deposition apparatus 100 illustrated in FIG. 1, the chamber 10 may accommodate the substrate temperature adjustment part 40 coupled to one end of the rotation shaft 22 and accommodate the substrate fixing part 50 coupled to one side of the substrate temperature adjustment part 40. The substrate temperature adjustment part 40 and the substrate fixing part 50 may rotate in conjunction with the rotation of the rotation shaft 22.

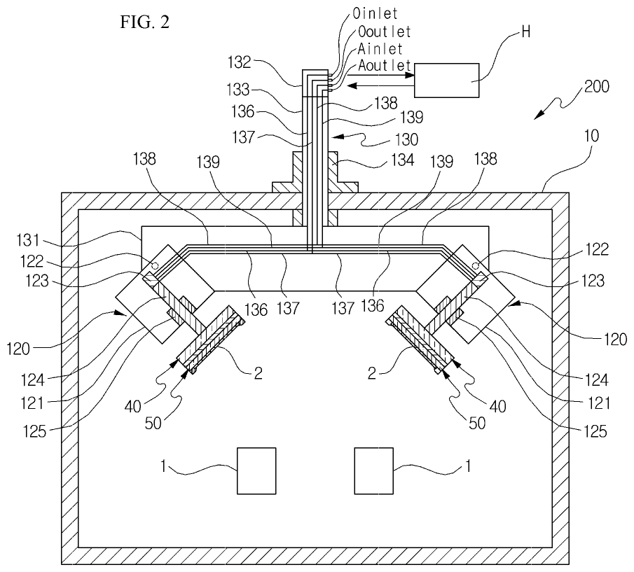

In this case, as illustrated in FIG. 2, the substrate temperature adjustment part 40 may include a first substrate temperature adjustment unit 41 coupled to one end of the rotation shaft 22, and a second substrate temperature adjustment unit 43 coupled to one side of the first substrate temperature adjustment unit 41 (a side opposite to the side of the first substrate temperature adjustment unit 41 to which the rotation shaft 22 is coupled). The above-mentioned flow paths may be provided in the first substrate temperature adjustment unit 41.

In addition, the substrate fixing part 50 may include a first fixing unit 52 having one side to which the second substrate temperature adjustment unit 43 is coupled, and a second fixing unit 54 coupled to the other side of the first fixing unit 52. The substrate 2 may be fixed between the first fixing unit 52 and the second fixing unit 54. For example, the substrate 2 may be a glass panel.

At least one evaporation source 1 may be provided at a lower end in the chamber 10. The substrate 2 fixed to the substrate fixing part 50 may be disposed to face the evaporation source 1 so that a front surface of the substrate 2 is exposed in a direction toward the evaporation source 1.

In this case, the “substrate fixing device” including the substrate temperature adjustment part 40 and the substrate fixing part 50 may be positioned above the evaporation source 1.

Therefore, the deposition material may be evaporated from the evaporation source 1 provided at the lower end in the chamber 10 and supplied toward the substrate 2 positioned above the evaporation source 1. For example, the deposition material may be a compound of alkaline metal halides such as cesium iodide and thallium iodide.

During the process of depositing the scintillator onto the substrate 2 by using the substrate deposition apparatus 100, the chamber 10 may be kept in the vacuum state, and the rotation shaft 22 rotates such that the deposition material evaporated from the evaporation source 1 may be uniformly deposited on the substrate 2. In this case, the deposition material may be deposited on the front surface of the substrate 2.

FIG. 2 is a conceptual view illustrating a substrate deposition apparatus 200 according to another embodiment of the present invention.

Referring to FIG. 2, unlike the substrate deposition apparatus 100 described with reference to FIG. 1, the substrate deposition apparatus 200 according to the present embodiment may be configured such that a plurality of rotation parts 120 is coupled to a single revolution part 130. Therefore, the substrate temperature adjustment part 40 and the substrate fixing part 50 may be coupled to each of the plurality of rotation parts 120, and the substrates 2 may be fixed to the substrate fixing parts 50, respectively.

The substrate deposition apparatus 200 includes a chamber 10 having therein a sealed space, the revolution part 130 connected to the revolution motor (not illustrated) and configured to be rotated by power transmitted from the revolution motor, and the plurality of rotation parts 120 coupled to the revolution part 130 and configured to revolve in conjunction with a rotation of the revolution part 130. In this case, the chamber 10 is identical to the chamber 10 illustrated in FIG. 1 in that the evaporation source 1 is provided at the lower end in the chamber 10.

The revolution part 130 includes a revolution part frame 131, and a revolution shaft 133 disposed at a central portion of the revolution part frame 131. The revolution part frame 131 may have a space capable of accommodating the plurality of rotation parts 120. In the present invention, the rotation part 120 may be coupled to the revolution part frame 131 by means of a tilting shaft 122.

The revolution shaft 133 may penetrate the upper wall of the chamber 10 and be partially accommodated in the chamber 10. For example, the revolution shaft 133 may have a cylindrical shape, and particularly, be made of aluminum (Al), copper (Cu), iron (Fe), or other metal alloys. In addition, the revolution part frame 131 may be positioned in the chamber 10. The plurality of rotation parts 120 coupled to the revolution part frame 131 may also be positioned in the chamber 10.

Like the substrate deposition apparatus 100 illustrated in FIG. 1, a gas inflow/outflow control part to be described below may also be connected to the chamber 10 and the substrate fixing part 50 of the substrate deposition apparatus 200 illustrated in FIG. 2. The configuration related to the gas inflow/outflow control part may be identical to that of the substrate deposition apparatus 100 illustrated in FIG. 1.

In addition, the revolution part 130 further includes a rotary joint 132 disposed at an upper side of the revolution shaft 133, and a sealing unit 134 disposed to be in close contact with an outer surface of the chamber 10 and configured to surround the revolution shaft 133.

The rotary joint 132 may be connected to an oil supply source (not illustrated) and a gas supply source to be described below. The rotary joint 132 may be connected to a heat exchanger H and exchange heat with oil that circulates in the substrate temperature adjustment part 40 coupled to each of the rotation parts 120. In this case, the rotary joint 132 may be identical to the rotary joint 21 illustrated in FIG. 1 except that the rotary joint 132 is disposed at the upper side of the revolution shaft 133.

As illustrated in FIG. 2, an oil inflow path 136, an oil outflow path 137, a gas inflow path 138, and a gas outflow path 139 may be formed in the revolution shaft 133 and configured to penetrate the revolution shaft 133 and be connected to an oil inlet Oᵢₙₗₑₜ, an oil outlet Oₒᵤₜₗₑₜ, a gas inlet Aᵢₙₗₑₜ, and a gas outlet Aₒᵤₜₗₑₜ of the rotary joint 132, respectively. In this case, the oil inlet Oᵢₙₗₑₜ and the oil outlet Oₒᵤₜₗₑₜ of the rotary joint 132 may be connected to the oil supply source, and the gas inlet Aᵢₙₗₑₜ and the gas outlet Aₒᵤₜₗₑₜ of the rotary joint 132 may be connected to the gas supply source.

The oil inflow path 136, the oil outflow path 137, the gas inflow path 138, and the gas outflow path 139 may be identical in configuration to the oil inflow path 24, the oil outflow path 25, the gas inflow path 26, and the gas outflow path 27, which are illustrated in FIG. 1, except that the oil inflow path 136, the oil outflow path 137, the gas inflow path 138, and the gas outflow path 139 are each divided and connected to the plurality of rotation parts 120. In addition, the configuration of the sealing unit 134 may also be identical to the configuration of the sealing unit 23 illustrated in FIG. 1.

In the substrate deposition apparatus 200 according to the present invention, the revolution part frame 131 may rotate in conjunction with the rotation of the revolution shaft 133 and rotate (revolve) the plurality of rotation parts 120, which is coupled to the revolution part frame 131, around the revolution shaft 133.

In addition, the rotation part 120 may be connected to a tilting motor (not illustrated) and independently and axially rotated around the tilting shaft 122 relative to the revolution part frame 131. The rotation part 120 may be connected to a rotation motor (not illustrated) and rotate the substrate temperature adjustment part 40 and the substrate fixing part 50 about a rotation shaft 124. In this case, the rotation motor may be disposed in the rotation part 120, and the tilting motor may be disposed in the revolution part frame 131 or the rotation part 120.

As illustrated in FIG. 2, the rotation part 120 further includes a rotation part main body 121, a rotary joint 123 disposed at an upper side of the rotation shaft 124 based on the rotation shaft 124, and a sealing unit 125 disposed to be in close contact with an inner surface of the rotation part main body 121 and configured to surround the rotation shaft 124.

The rotation part main body 121 is a kind of atmospheric pressure box (ATM box). As illustrated in FIG. 2, the rotation part main body 121 may be connected to the revolution part frame 131 by means of the tilting shaft 122 and independently and axially rotated about the tilting shaft 122 relative to the revolution part frame 131.

In this case, the configuration of the rotary joint 123 illustrated in FIG. 2 may be identical to the configuration of the rotary joint 21 illustrated in FIG. 1. The oil inflow path 136, the oil outflow path 137, the gas inflow path 138, and the gas outflow path 139 may be divided and connected to the rotary joints 123.

In addition, the rotation shaft 124 and the sealing unit 125 illustrated in FIG. 2 may be identical in shape and material to the rotation shaft 22 and the sealing unit 23 illustrated in FIG. 1.

Meanwhile, in the case in which the substrate deposition apparatus 200 includes the plurality of rotation parts 120 as illustrated in FIG. 2, the rotation parts 120 may have the rotary joints 123, respectively.

In this case, because of the nature of the rotary joint 123, particles may be produced by friction that occurs when the rotation shaft 124 rotates. Therefore, the rotary joint 123 cannot be used in the chamber 10 in the vacuum state illustrated in FIG. 2, and the rotary joint 123 may be positioned in the rotation part main body 121 in which a pressure equal to the atmospheric pressure is maintained as illustrated in FIG. 2.

In addition, although not illustrated, like the rotary joint 21 which is illustrated in FIG. 1, the rotary joint 123 of the substrate deposition apparatus 200 illustrated in FIG. 2 includes the oil inlet, the oil outlet, the gas inlet, and the gas outlet.

The oil inlet and the oil outlet of the rotary joint 123 may be connected to the oil inflow path 136 and the oil outflow path 137, respectively, and the gas inlet and the gas outlet of the rotary joint 123 may be connected to the gas inflow path 138 and the gas outflow path 139, respectively.

In this case, although not illustrated in FIG. 2, the oil inflow path and the oil outflow path may be formed in the rotation shaft 124 and connected to the oil inlet and the oil outlet of the rotary joint 123, respectively. In addition, the gas inflow path and the gas outflow path may be formed in the rotation shaft 124 and connected to the gas inlet and the gas outlet of the rotary joint 123, respectively.

The oil inflow path, the oil outflow path, the gas inflow path, and the gas outflow path, which are formed in the rotation shaft 124 of the substrate deposition apparatus 200, may be identical in configuration to the oil inflow path 24, the oil outflow path 25, the gas inflow path 26, and the gas outflow path 27, which are illustrated in FIG. 1, except that the oil inflow path, the oil outflow path, the gas inflow path, and the gas outflow path are respectively connected to the oil inflow path 136, the oil outflow path 137, the gas inflow path 138, and the gas outflow path 139 that pass through the inside of the revolution shaft 133.

For example, in the substrate deposition apparatus 200 illustrated in FIG. 2, the oil may be supplied to a flow path provided in the substrate temperature adjustment part 40 coupled to one end of the rotation shaft 124 through the oil inflow path and the oil outflow path formed in the rotation shaft 124, and the oil may circulate in the flow path and then be discharged from the flow path.

In addition, the gas may be supplied into the substrate fixing part 50 coupled to one side of the substrate temperature adjustment part 40 through the gas inflow path and the gas outflow path formed in the rotation shaft 124, and the gas may be discharged from the inside of the substrate fixing part 50.

The substrate deposition apparatus 200 described with reference to FIG. 2 may include the revolution part 130 having the revolution shaft 133, and the plurality of rotation parts 120 coupled to the revolution part 130 may be accommodated in the chamber 10.

In the substrate deposition apparatus 200 illustrated in FIG. 2, when the revolution shaft 133 disposed at the central portion of the revolution part frame 131 rotates (revolves), the revolution part frame 131 rotates in conjunction with the rotation of the revolution shaft 133, and the plurality of rotation parts 120 coupled to the revolution shaft 133 may rotate (revolve) around the revolution shaft 133.

Therefore, the substrate deposition apparatus 200 having the plurality of rotation parts 120 may deposit the deposition material on the plurality of substrates 2 fixed to the substrate fixing parts 50 through a single deposition process, which makes it possible to deposit the deposition material on the plurality of substrates 2.

In addition, in the substrate deposition apparatus 200, the plurality of rotation parts 120 independently and axially rotates about the tilting shafts 122, respectively, relative to the revolution part frame 131. Therefore, as illustrated in FIG. 2, the substrate 2 fixed to the substrate fixing part 50 may be disposed to be inclined instead of facing the evaporation source 1.

Therefore, the substrate deposition apparatus 200 may easily adjust relative positions and directions of the substrates with respect to the evaporation source 1 by revolving the revolution part 130 and tilting and rotating the rotation parts 120, thereby maximizing deposition efficiency.

The substrate temperature adjustment part 40 and the substrate fixing part 50 provided in the substrate deposition apparatus 200 illustrated in FIG. 2 may be identical in configuration to the substrate temperature adjustment part 40 and the substrate fixing part 50 that are illustrated in FIG. 1.

Meanwhile, in the substrate deposition apparatus 200 illustrated in FIG. 2, an oil tank (not illustrated) may be disposed in the revolution part frame 131 in order to uniformly control the temperature of the substrate temperature adjustment parts 40 without separately defining oil inflow/outflow paths in the respective substrate temperature adjustment parts 40 from the oil supply source disposed outside the chamber. For example, the oil tank may be disposed in the revolution part frame 131 and provided below the revolution shaft 133.

The oil tank may be connected to the oil inflow path 136 and supplied with the oil from the outside oil supply source. The oil tank may be connected to the oil outflow path 137 and discharge, to the oil supply source, the oil discharged from the substrate temperature adjustment parts 40 respectively coupled to the rotation parts 120.

In this case, the oil inflow path 136 and the oil outflow path 137 may branch off from the oil tank and be connected to each of the rotation parts 120.

The oil tank may serve as a damper for damping heat transferred from the heat exchanger H. In addition, the oil tank may collect therein the oil supplied from the outside oil supply source and serve as a branch start point at which the oil is divided and supplied to the substrate temperature adjustment parts 40 from the oil tank.

Therefore, in the case in which the substrate deposition apparatus 200 illustrated in FIG. 2 includes the oil tank, conditions of branch paths of the oil inflow path 136 and the oil outflow path 137 connected to the respective substrate temperature adjustment parts 40 from the oil tank may be equally set, which makes it possible to uniformly control the temperatures of the substrate temperature adjustment parts 40 during the process of depositing the scintillator.

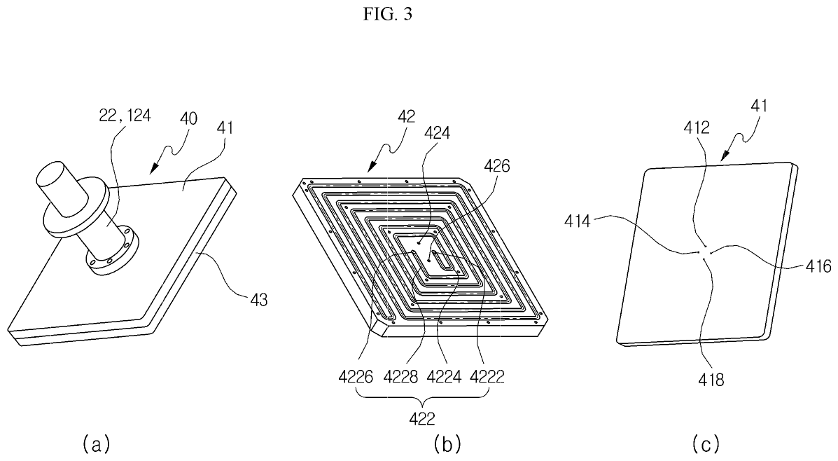

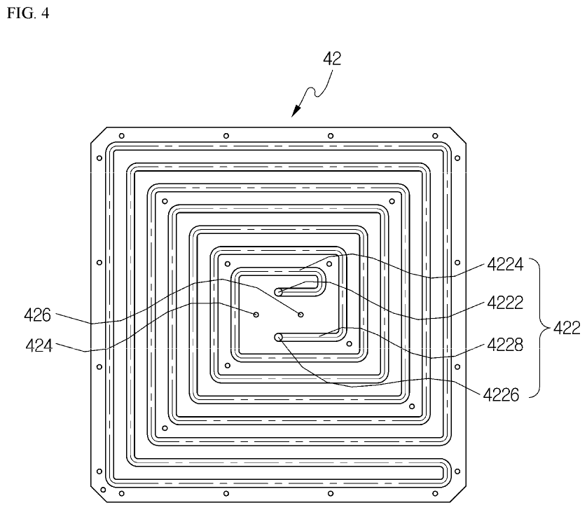

FIG. 3 is a view illustrating the substrate temperature adjustment part 40 provided in the substrate deposition apparatus 100 or 200 according to the present invention, and FIG. 4 is a view illustrating a flow path 422 provided on the substrate temperature adjustment part 40 according to the present invention. In this case, (a) of FIG. 3 is a view illustrating an overall shape of the substrate temperature adjustment part 40, (b) of FIG. 3 is a perspective view illustrating an oil flow unit 42, and (c) of FIG. 3 is a view illustrating the first substrate temperature adjustment unit 41 of the substrate temperature adjustment part 40.

Referring to (a) of FIG. 3, the substrate temperature adjustment part 40 may include the first substrate temperature adjustment unit 41 coupled to the rotation shaft 22 or 124, and the second substrate temperature adjustment unit 43 coupled to the other side of the first substrate temperature adjustment unit 41. The oil flow unit 42 illustrated in (b) of FIG. 3 may be provided in the first substrate temperature adjustment unit 41.

The substrate fixing part 50 may be coupled to one side of the substrate temperature adjustment part 40. The substrate temperature adjustment part 40 according to the present invention may transfer heat to the substrate fixing part 50 and the substrate 2 fixed to the substrate fixing part 50.

The first substrate temperature adjustment unit 41 and the second substrate temperature adjustment unit 43 may be made of the same material. In detail, the first substrate temperature adjustment unit 41 and the second substrate temperature adjustment unit 43 may be manufactured by using a metallic material such as aluminum (Al) and copper (Cu). The first substrate temperature adjustment unit 41 and the second substrate temperature adjustment unit 43 may be made of the same material, such that the first substrate temperature adjustment unit 41 and the second substrate temperature adjustment unit 43 may be identical to each other in terms of a specific heat, a strain rate with respect to a temperature, and the like.

With the above-mentioned configuration, it is possible to prevent damage to the substrate 2 fixed to the substrate fixing part 50 due to deformation of the entire substrate temperature adjustment part 40 caused by thermal unconformity occurring between the first substrate temperature adjustment unit 41 and the second substrate temperature adjustment unit 43.

The oil flow unit 42 illustrated in FIG. 3B may be provided in the first substrate temperature adjustment unit 41 and coupled to the first substrate temperature adjustment unit 41 by welding.

The oil flow unit 42 may include the flow path 422 in which the oil introduced from the oil supply source circulates.

Referring to FIGS. 3B and 4, the flow path 422 includes an oil inlet hole 4222 connected to the oil inflow path 24, an oil inflow line 4224 along which the oil introduced into the flow path 422 through the oil inlet hole 4222 circulates in the flow path 422, an oil outlet hole 4226 connected to the oil outflow path 25, and an oil outflow line 4228 along which the oil circulating in the flow path 422 is discharged through the oil outlet hole 4226.

The flow path 422 may allow the oil supplied from the oil supply source to circulate in the flow path 422 and transfer heat to the substrate 2 fixed to the substrate fixing part 50 during the process of depositing the deposition material on the substrate 2. In this case, radiation, convection, conduction, and the like may be used to transfer heat from the flow path 422 to the substrate fixing part 50.

As described above, the oil inflow path 24 and the oil inlet hole 4222 of the flow path 422 may have the same diameter, and the oil outflow path 25 and the oil outlet hole 4226 of the flow path 422 may have the same diameter.

A temperature of the oil circulating in the flow path 422 may be 30° C. to 200° C. The flow path 422 may be formed to prevent, as much as possible, the leakage of the oil to a portion other than the flow path 422.

In addition, in the present invention, the oil may be used as a heat transfer medium for transferring heat to the substrate 2. The process of depositing the scintillator may be stably performed because the oil may be continuously changed in temperature. Because the oil is excellent in specific heat and heat transfer efficiency, the oil may be not only heated, but also cooled, and the oil may also have a wide temperature range in which heat is transferred.

Therefore, the oil is used as a heat transfer medium in the present invention, which makes it possible to precisely control the temperature of the substrate temperature adjustment part 40 configured to transfer heat to the substrate 2.

As illustrated in FIG. 4, the oil inflow line 4224 and the oil outflow line 4228 of the flow path 422 have edge portions formed gently, which makes it possible to reduce vortices that may occur when the oil circulates along the edge portions.

Meanwhile, a deviation of temperature uniformity in the flow path 422 may be kept as small as possible to efficiently deposit the scintillator. The biggest reason why the temperature of the oil changes in the flow path 422 is that a temperature of the oil in the oil inflow line 4224 is higher than a temperature of the oil in the oil outflow line 4228.

Therefore, in the present invention, as illustrated in FIG. 4, the oil inflow line 4224 and the oil outflow line 4228 of the flow path 422 may be disposed to intersect each other in order to maintain temperature uniformity of the entire flow path 422.

In this case, as a width by which the oil inflow line 4224 and the oil outflow line 4228 intersect each other is decreased, the temperature uniformity of the entire flow path 422 may be improved.

Meanwhile, a rate of change in temperature in the flow path 422 made by the heat exchanger H may be decreased as the width by which the oil inflow line 4224 and the oil outflow line 4228 intersect each other is decreased. Therefore, the width by which the oil inflow line 4224 and the oil outflow line 4228 are disposed to intersect each other may be set within a range in which a rate of change in temperature required for the process of depositing the scintillator is ensured.

Referring to (c) of FIG. 3, the first substrate temperature adjustment unit 41 includes an inflow oil passing hole 412 through which the oil inflow path 24 passes, and an outflow oil passing hole 414 through which the oil outflow path 25 passes, and the inflow oil passing hole 412 and the outflow oil passing hole 414 are formed at a central portion of the first substrate temperature adjustment unit 41.

The oil inflow path 24 may pass through the inflow oil passing hole 412 and connect to the oil inlet hole 4222, and the oil outflow path 25 may pass through the outflow oil passing hole 414 and connect to the oil outlet hole 4226.

In this case, seals (not illustrated) may be provided in the inflow oil passing hole 412 and the outflow oil passing hole 414 to prevent the leakage of the oil. In addition, the oil inflow path 24 and the inflow oil passing hole 412 may have the same diameter, and the oil outflow path 25 and the outflow oil passing hole 414 may have the same diameter.

Referring to (b) and (c) of FIG. 3 and FIG. 4, the first substrate temperature adjustment unit 41 further includes an inflow gas passing hole 416 through which the gas inflow path 26 passes, and an outflow gas passing hole 418 through which the gas outflow path 27 passes, and the inflow gas passing hole 416 and the outflow gas passing hole 418 are formed at the central portion of the first substrate temperature adjustment unit 41.

In addition, the oil flow unit 42 further includes an inflow gas passing hole 424 through which the gas inflow path 26 passes, and an outflow gas passing hole 426 through which the gas outflow path 27 passes, and the inflow gas passing hole 424 and the outflow gas passing hole 426 are formed at the central portion of the oil flow unit 42.

In the embodiment of the present invention, the gas inflow path 26 may be connected to a gas supply hole 524 provided in the substrate fixing part 50 while passing through the inflow gas passing hole 416 provided in the first substrate temperature adjustment unit 41 and the inflow gas passing hole 424 provided in the oil flow unit 42. The gas outflow path 27 may be connected to a gas discharge hole 525 provided in the substrate fixing part 50 while passing through the outflow gas passing hole 418 provided in the first substrate temperature adjustment unit 41 and the outflow gas passing hole 426 provided in the oil flow unit 42.

In this case, the gas inflow path 26, the inflow gas passing hole 416 provided in the first substrate temperature adjustment unit 41, and the inflow gas passing hole 424 provided in the oil flow unit 42 may have the same diameter. The gas outflow path 27, the outflow gas passing hole 418 provided in the first substrate temperature adjustment unit 41, and the outflow gas passing hole 426 provided in the oil flow unit 42 may have the same diameter.

In addition, seals (not illustrated) may be provided in the inflow gas passing hole 416 provided in the first substrate temperature adjustment unit 41, the inflow gas passing hole 424 provided in the oil flow unit 42, the outflow gas passing hole 418 provided in the first substrate temperature adjustment unit 41, and the outflow gas passing hole 426 provided in the oil flow unit 42 to prevent the oil from flowing into the passing holes.

Although not illustrated, the second substrate temperature adjustment unit 43 may also have an inflow gas passing hole through which the gas inflow path 26 passes, and an outflow gas passing hole through which the gas outflow path 27 passes, and the inflow gas passing hole and the outflow gas passing hole may be formed at a central portion of the second substrate temperature adjustment unit 43.

In the embodiment of the present invention, the second substrate temperature adjustment unit 43 has a smaller thickness than the first substrate temperature adjustment unit 41 so that the heat may be more efficiently transferred to the substrate 2 fixed to the substrate fixing part 50.

When the second substrate temperature adjustment unit 43 has a smaller thickness than the first substrate temperature adjustment unit 41 as described above, an interval between the flow path 422, in which the oil circulates, and the substrate 2 may decrease, thereby more efficiently transferring heat to the substrate 2 during the process of depositing the scintillator.

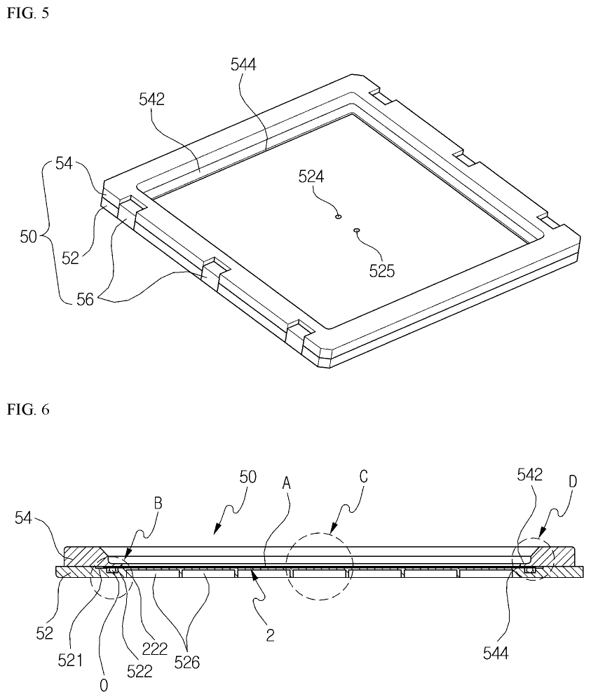

FIG. 5 is a view illustrating an overall shape of the substrate fixing part 50 provided in the substrate deposition apparatus 100 or 200 according to the present invention, and FIG. 6 is a cross-sectional side view illustrating the substrate fixing part 50 according to the present invention. The substrate 2 is not illustrated in FIG. 5.

Referring to FIGS. 5 and 6, the substrate fixing part 50 includes the first fixing unit 52 having one side to which the second substrate temperature adjustment unit 43 is coupled, and the second fixing unit 54 coupled to the other side of the first fixing unit 52 and having a picture frame structure so that the front surface of the substrate 2 is exposed.

The substrate 2 may be fixed between the first fixing unit 52 and the second fixing unit 54. In detail, the substrate fixing part 50 may fix the substrate 2 as the substrate 2 is seated on the first fixing unit 52 and then the second fixing unit 54 is positioned on the substrate 2.

In this case, the substrate 2 may be positioned between the first fixing unit 52 and the second fixing unit 54 so that only an active area A of the substrate 2 is exposed, and then the first fixing unit 52 and the second fixing unit 54 may be coupled to each other by means of a plurality of connection portions 56. In the embodiment of the present invention, the active area A of the substrate 2 may be a front portion of the substrate.

The active area A of the substrate 2 may mean a region of the substrate 2 in which the scintillator material supplied from the evaporation source 1 is deposited. The active area A of the substrate 2 may be variously set depending on the purpose of the substrate 2 by adjusting a thickness by which a rim portion 542 provided on an inner peripheral surface of the second fixing unit 54 protrudes toward a center of the second fixing unit 54.

In addition, the first fixing unit 52 and the second fixing unit 54 may be made of the same material. In detail, the first fixing unit 52 and the second fixing unit 54 may be made of a metallic material such as aluminum (Al) and copper (Cu). As the first fixing unit 52 and the second fixing unit 54 are made of the same material, the first fixing unit 52 and the second fixing unit 54 may be identical to each other in terms of a specific heat, a strain rate with respect to a temperature, and the like.

With the above-mentioned configuration, it is possible to prevent damage to the substrate 2 fixed to the substrate fixing part 50 due to deformation of the substrate fixing part 50 caused by thermal unconformity between the first fixing unit 52 and the second fixing unit 54 caused by heat transferred to the substrate fixing part 50 from the substrate temperature adjustment part 40.

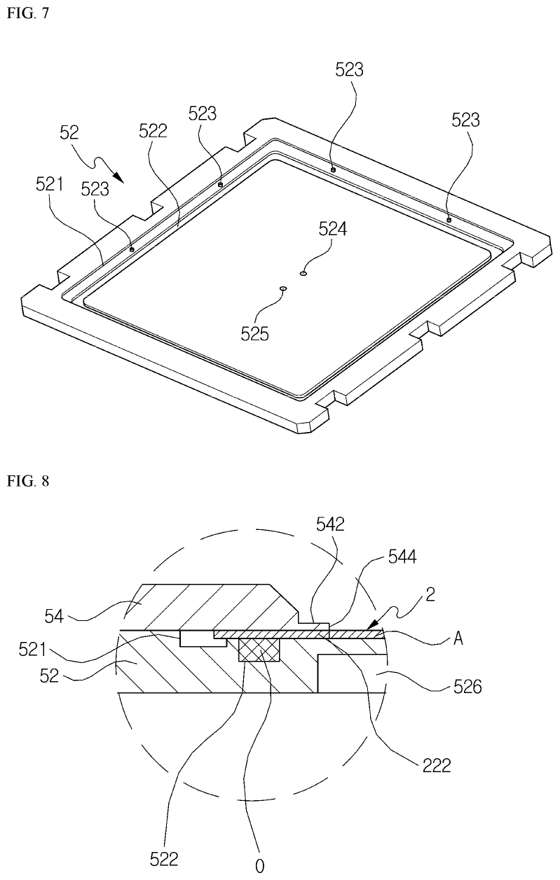

FIG. 7 is a view illustrating the first fixing unit 52 of the substrate fixing part 50 according to the present invention, and FIG. 8 is an enlarged view of part B in FIG. 6.

Referring to FIGS. 6 to 8, the first fixing unit 52 includes a groove portion 521 formed along an inner periphery of the first fixing unit 52, a sealing member accommodation portion 522 spaced apart from the groove portion 521 at a predetermined interval, disposed inside the groove portion 521, and formed along the inner periphery of the first fixing unit 52, and one or more guide pins 523 formed between the groove portion 521 and the sealing member accommodation portion 522.

As illustrated in FIGS. 6 and 8, the groove portion 521 defines a predetermined available space to prevent an outer end of the substrate 2 from coming into direct contact with the first fixing unit 52. Therefore, at the time of separating the substrate 2 from the first fixing unit 52 after the process of depositing the scintillator is completed, the substrate 2 may be detached through the groove portion 521, which makes it possible to prevent damage to the substrate 2.

As illustrated in FIGS. 6 and 8, a sealing member O may be accommodated in the sealing member accommodation portion 522. The sealing member O accommodated in the sealing member accommodation portion 522 may seal a gap between the substrate 2 and the first fixing unit 52. For example, the sealing member O may be an O-ring.

The guide pins 523 may guide the substrate 2 when the substrate 2 is seated on the first fixing unit 52. In addition, the guide pin 523 may be made of a material such as Teflon strong against static electricity, thereby preventing damage to a thin-film transistor (TFT) area of the substrate 2 seated on the first fixing unit 52.

As illustrated in FIGS. 5 and 7, the first fixing unit 52 includes a gas supply hole 524 through which the gas is injected between the first fixing unit 52 and the rear surface of the substrate 2 by the gas inflow/outflow control part, and a gas discharge hole 525 through which the gas is discharged from the space between the first fixing unit 52 and the rear surface of the substrate 2.

As described above, the gas inflow path 26 and the gas supply hole 524 may have the same diameter, and the gas outflow path 27 and the gas discharge hole 525 may have the same diameter.

In addition, the gas supply hole 524 and the gas discharge hole 525 may be formed at the positions coincident with the gas holes (the inflow gas passing hole 416, the inflow gas passing hole 424, the outflow gas passing hole 418, and the outflow gas passing hole 426) formed in the substrate temperature adjustment part 40.

Therefore, the gas may be supplied into the space between the first fixing unit 52 and the rear surface of the substrate 2 through the gas supply hole 524 via the gas inflow path 26. In addition, the gas may be discharged from the space between the first fixing unit 52 and the rear surface of the substrate 2 through the gas discharge hole 525 via the gas outflow path 27.

Meanwhile, the gas, which is supplied into the space between the first fixing unit 52 and the rear surface of the substrate 2 may be inert gas (noble gas) such as helium (He).

According to the periodic table, helium is smaller in mass next to hydrogen, has almost no reactivity, and has a fine particle (the atomic number of helium is 2). Because of the particle characteristics of helium, helium may leak from a gap between the sealing member O and the substrate 2 and flow into the chamber 10 even though the sealing member O is inserted into the sealing member accommodation portion 522 as described above.

Therefore, the gas supply hole 524 and the gas discharge hole 525 may be spaced apart from the sealing member accommodation portion 522 as much as possible and particularly positioned at a center of the first fixing unit 52 in order to maximally prevent the leak of helium supplied between the first fixing unit 52 and the rear surface of the substrate 2.

As illustrated in FIG. 6, one or more recessed portions 526 may be formed in a lower portion of the first fixing unit 52.

In the embodiment of the present invention, a total sum of a weight of the first fixing unit 52 and a weight of the second fixing unit 54 (an overall weight of the substrate fixing part 50) may be kept constant regardless of a change in sizes of the first and second fixing units 52 and 54.

For example, when a size of the substrate 2 decreases, a size of the second fixing unit 54 increases to fix the substrate 2, which may increase a weight of the second fixing unit 54. If the weight of the first fixing unit 52 is maintained, an overall weight of the substrate fixing part 50 increases because of an increase in weight of the second fixing unit 54, which may degrade efficiency in transferring heat to the substrate 2 through the substrate fixing part 50.

Therefore, in the embodiment of the present invention, a total sum of a weight of the first fixing unit 52 and a weight of the second fixing unit 54 may be kept constant regardless of a change in sizes of the first fixing unit 52 and the second fixing unit 54.

As described above, the active area A of the substrate 2 may be variously set depending on the purpose of the substrate 2 by adjusting a thickness by which the rim portion 542 provided on the inner peripheral surface of the second fixing unit 54 protrudes toward the center of the second fixing unit 54.

In this case, since the thickness by which the rim portion 542 protrudes toward the center of the second fixing unit 54 is adjusted, the first fixing unit 52 may also be replaced when the weight of the second fixing unit 54 is changed, such that the total sum of the weights of the first and second fixing units 52 and 54 is kept constant.

In the embodiment of the present invention, at the time of replacing the first fixing unit 52, the first fixing unit 52 is replaced with a new first fixing unit different in number of recessed portions 526, which is formed in the lower portion of the first fixing unit 52, from the first fixing unit 52 without changing an overall dimension of the first fixing unit 52. Therefore, the total sum of the weights of the first and second fixing units 52 and 54 may be kept constant.

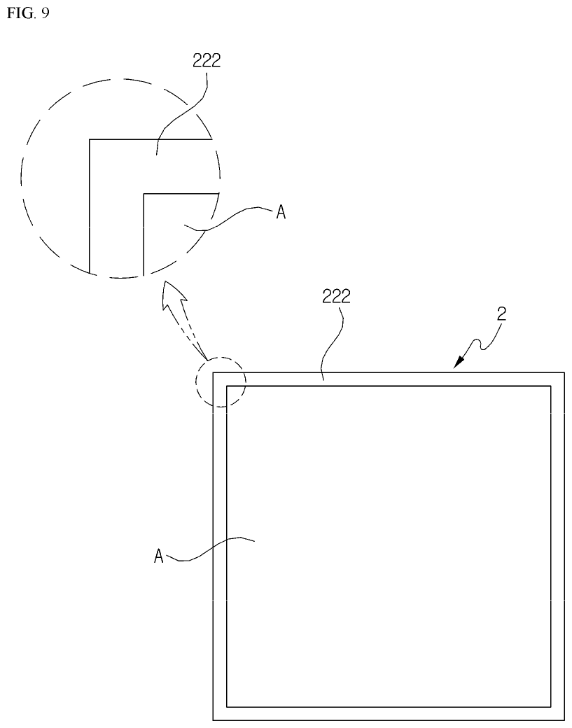

FIG. 9 is a view illustrating an edge portion 222 formed on the substrate 2 according to the present invention.

In the embodiment of the present invention, stress may be applied to the sealing member O from the outside of the active area A of the substrate 2 in order to form the space between the first fixing unit 52 and the rear surface of the substrate 2 and inject the gas into the space.

Referring to FIGS. 6, 8, and 9, in the present invention, the edge portion 222 may be provided outside the active area A in order to inject the gas into the space between the first fixing unit 52 and the rear surface of the substrate 2.

As illustrated in FIG. 8, the edge portion 222 may be disposed between the second fixing unit 54 and the sealing member O and apply stress to the sealing member O. Since the edge portion 222 applies the stress to the sealing member O, it is possible to stably form the space between the first fixing unit 52 and the rear surface of the substrate 2 so that the gas may be injected into the space.

Particularly, the edge portion 222 may be formed to have a predetermined area along an outer edge portion of the substrate 2.

Meanwhile, the edge portion 222, except for the active area A of the substrate 2 in which the deposition material is deposited, may be separated from the active area A after the process of depositing the scintillator is completed.

When the process of depositing the scintillator is completed, the substrate 2 on which the deposition material is completely deposited needs to be detached from the first fixing unit 52, but the substrate 2 is sometimes not easily detached because of adhesion between the sealing member O and the substrate 2. In addition, the outside of the front surface of the substrate 2 (the inside of the chamber 10) is in a vacuum state and the gas is injected into the space between the first fixing unit 52 and the rear surface of the substrate 2 during the process of depositing the scintillator. Therefore, there is a likelihood that the substrate 2 is bent and damaged by a difference in pressure between the outside of the front surface of the substrate 2 and the space between the first fixing unit 52 and the rear surface of the substrate 2.

To solve the problem, in the present invention, as illustrated in FIG. 8, the sealing member O accommodated in the sealing member accommodation portion 522 may be in surface contact with the substrate 2 instead of being in line contact with the substrate 2.

For example, a surface of the sealing member O illustrated in FIG. 8, which is in contact with the substrate 2, may have a quadrangular shape. In addition, the groove portion 521 may define a predetermined available space that prevents the outer end of the substrate 2 from coming into direct contact with the first fixing unit 52 as described above, thereby preventing the outer end of the substrate 2 from being bent.

As illustrated in FIG. 8, a cross-sectional shape of the sealing member O is not limited to a quadrangular shape, but may be various shapes such as a circular shape, a triangular shape, a pentagonal shape, a hexagonal shape, or the like.

Alternatively, the sealing member accommodation portion 522 may have at least two accommodation grooves (not illustrated), such that at least two sealing members O may be accommodated in the accommodation grooves.

In a case in which two or more sealing members O are provided, a cross-sectional shape of the sealing member O may be a circular shape. Even in this case, the plurality of sealing members O accommodated in the accommodation groove may be in surface contact with the substrate 2, like the embodiment illustrated in FIG. 8.

With the above-mentioned configuration, since the sealing member O is in surface contact with the substrate 2, the glass portion may be easily attached or detached, which makes it possible to prevent damage to the substrate 2 caused when the substrate 2 is bent.

Meanwhile, in a case in which a surface of the sealing member O is coated with a material such as Teflon that may reduce a bonding force and then used, a single sealing member O having a circular cross-section may be disposed in the sealing member accommodation portion 522.

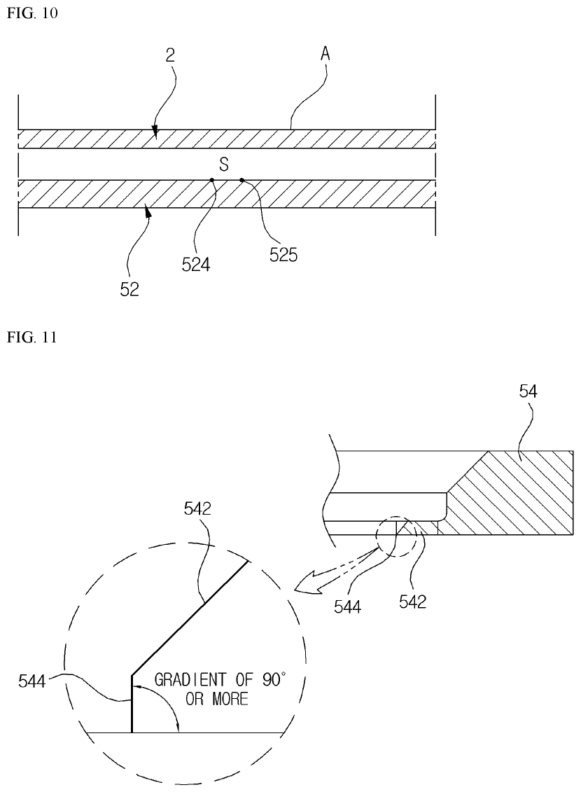

FIG. 10 is a view illustrating a space S formed between the substrate 2 and the first fixing unit 52 according to the present invention (an enlarged view of part C in FIG. 6). The recessed portion 526 is not illustrated in FIG. 10.

Referring to FIG. 10, the space may be formed between the first fixing unit 52 and the rear surface of the substrate 2 as described above. In the present invention, the space is defined as the space S.

As described above, the gas may be injected into the space S through the gas supply hole 524, and the gas may be discharged from the space S through the gas discharge hole 525.

FIG. 11 is an enlarged view of a part of the second fixing unit 54 of the substrate fixing part 50 according to the present invention (an enlarged view of part D in FIG. 6). The substrate 2 is not illustrated in FIG. 11.

Referring to FIG. 11, the second fixing unit 54 includes a rim portion 542 formed on an inner peripheral surface of the second fixing unit 54, and a mask area 544 formed at an end of the rim portion 542.

As described above, the active area A of the substrate 2 may be variously set depending on the purpose of the substrate 2 by adjusting a thickness by which the rim portion 542 provided on the inner peripheral surface of the second fixing unit 54 protrudes toward the center of the second fixing unit 54.

A thickness (height) of the rim portion 542 based on a vertical direction may be set as a minimum thickness in consideration of ease of processing and manufacturing cost of the second fixing unit 54 so that the process of depositing the deposition material in the active area A of the substrate 2 may be smoothly performed.

Referring to the enlarged view in FIG. 11, the mask area 544 is a portion that comes into contact with the end of the active area A of the substrate 2. In this case, a thickness (height) of the mask area 544 based on the vertical direction may be set as a minimum thickness in consideration of ease of processing and manufacturing cost of the second fixing unit 54 so that the process of depositing the deposition material in the active area A may be smoothly performed.

Meanwhile, at the time of depositing the deposition material in the active area A of the substrate 2, the deposition material is attached in the form of a slope to the mask area 544, which may cause a problem of deterioration in deposition efficiency.

To solve the problem, in the embodiment of the present invention, the mask area 544 may be inclined in a direction toward the central portion of the second fixing unit 54 with respect to a lower surface of the rim portion 542.

For example, as illustrated in the enlarged view in FIG. 11, an inclination angle of the mask area 544 may be set to have an angle larger than 90 degrees in the direction toward the central portion of the second fixing unit 54 with respect to the lower surface of the rim portion 542.

With the above-mentioned configuration, the amount of deposition material, which is deposited in the active area A of the substrate 2 and attached in the form of a slope in the mask area 544, is minimized, such that the substrate 2 may be more easily separated from the second fixing unit 54 after the process of depositing the scintillator is completed, which makes it possible to improve efficiency in depositing the scintillator.

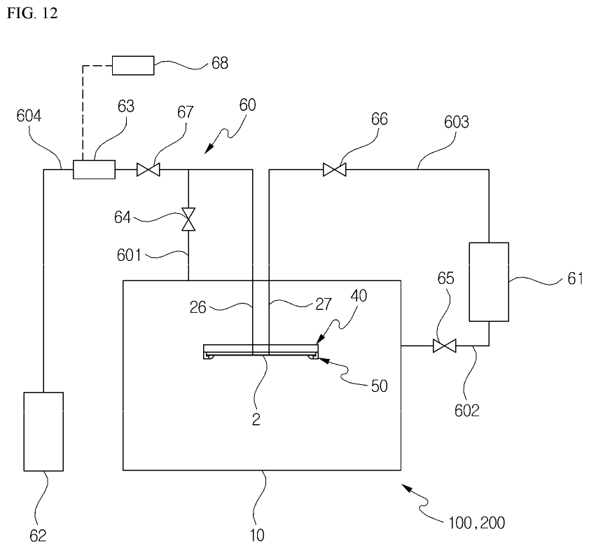

FIG. 12 is a view illustrating a configuration of a gas inflow/outflow control part 60 provided in the substrate deposition apparatus 100 or 200 according to the present invention. In FIG. 12, the detailed configurations of the evaporation source 1, the rotation parts 20 and 120, and the revolution part 130 are briefly illustrated or omitted.

In the substrate deposition apparatus 100 or 200 according to the present invention, the backside cooling refers to a method of adjusting the heat to be transferred to the substrate 2 by convection by means of the gas supplied into the space S by supplying the gas into the space S.

In the present invention, there are radiation and conduction in addition to convection as the method of transferring heat from the substrate temperature adjustment part 40 to the substrate fixing part 50 and the substrate 2 fixed to the substrate fixing part 50.

The heat transfer by radiation may increase a temperature of the substrate 2 by using radiant heat. However, the heat transfer by radiation cannot reduce the temperature of the substrate 2 and makes it difficult to precisely control the temperature.

In addition, in the case of the heat transfer by conduction, an area of contact portions of metal molecules of the substrate temperature adjustment part 40 and metal molecules the substrate fixing part 50 are about 1% of the entire surface area of the substrate temperature adjustment part 40 and the substrate fixing part 50 because of surface flatness of the substrate fixing part 50 and the substrate temperature adjustment part 40 made of a metallic material. In a case in which an electrostatic chuck (ESC) is used to increase an area in which the substrate temperature adjustment part 40 and the substrate fixing part 50 are in contact with one another, there is a high likelihood that the thin-film transistor (TFT) area on the substrate 2 may be damaged.

Therefore, in the present invention, in addition to radiation or conduction, the heat to be transferred to the substrate 2 by convection by means of the gas supplied into the space S is adjusted by supplying the gas into the space S.

In general, the substrate 2 may be made of a glass panel material, and there is a very high risk that the soft substrate 2 is damaged even by a low pressure.

In the present invention, the inside of the chamber 10 may be formed in a vacuum state in advance to enable the process of depositing the scintillator. In this case, the substrate 2 may be damaged by a difference in pressure between the space S and the inside of the chamber 10 unless the space S is also formed in the vacuum state in the step of forming the inside of the chamber 10 in the vacuum state in advance. However, when the substrate 2 is not soft in the embodiment of the present invention, the space S is not necessarily formed in the vacuum state as described above.

In the step of forming the inside of the chamber 10 into the vacuum state in advance, pumping is performed to form both the inside of the chamber 10 and the space S in the vacuum state. However, if the pumping is performed in the state in which the inside of the chamber 10 and the space S are separated from each other, there is a problem in that pumping speeds for both the inside of the chamber 10 and the space S need to be controlled.

To prevent the problem, the space S and the internal space of the chamber 10 may be connected to each other at the time of forming the inside of the chamber 10 in the vacuum state.

Referring to FIG. 12, the gas inflow/outflow control part 60 includes a pump 61 connected to the space S through the gas discharge hole 525 and configured to perform pumping on the space S at a predetermined pumping speed, a gas supply source 62 connected to the space S through the gas supply hole 524 and configured to accommodate the gas supplied into the space S, and a pressure controller 63 connected to the gas supply source 62 and configured to adjust a pressure of the gas to be supplied into the space S.

In this case, the pressure controller 63 may be disposed between the gas supply source 62 and the space S. In addition, the gas accommodated in the gas supply source 62 may be inert gas, particularly, helium.

In addition, the gas inflow/outflow control part 60 further includes a first valve 64 provided between the chamber 10 and the space S, a second valve 65 provided between the chamber 10 and the pump 61, a third valve 66 provided between the pump 61 and the space S, and a fourth valve 67 provided between the space S and the pressure controller 63. For example, the first valve 64, the second valve 65, the third valve 66, and the fourth valve 67 may each be, but not limited to, a normal open valve.

Meanwhile, the second valve 65 may be provided in plural, and the plurality of second valves 65 are different from one another in terms of flow rates of the air discharged from the inside of the chamber 10. The second valve 65 may be configured as a pump. In addition, the third valve 66 may also be provided in plural, and the plurality of third valves 66 are different from one another in terms of flow rates of the gas discharged from the space S.

In the embodiment of the present invention, the operation of the gas inflow/outflow control part 60 may be controlled by a main controller 68.

The gas inflow/outflow control part 60 further includes a first gas discharge line 601 having one side connected to the chamber 10 and the other side connected to or separated from the space S, a second gas discharge line 602 having one side connected to the chamber 10 and the other side connected to or separated from the pump 61, a third gas discharge line 603 having one side connected to the pump 61 and the other side connected to or separated from the space S, and a gas supply line 604 having one side connected to the gas supply source 62 and the other side connected to or separated from the space S.

In this case, the first valve 64 may be provided in the first gas discharge line 601, the second valve 65 may be provided in the second gas discharge line 602, the third valve 66 may be provided in the third gas discharge line 603, and the pressure controller 63 and the fourth valve 67 may be provided in the gas supply line 604.

The first gas discharge line 601 may be connected to or separated from the space S through the gas inflow path 26 as the first valve 64 is opened or closed. For example, the first gas discharge line 601 may be connected to the gas inflow path 26 when the first valve 64 is opened.

The second gas discharge line 602 may be connected to or separated from the pump 61 as the second valve 65 is opened or closed. For example, the second gas discharge line 602 may be connected to the pump 61 when the second valve 65 is opened.

The third gas discharge line 603 may be connected to or separated from the space S through the gas outflow path 27 as the third valve 66 is opened or closed. For example, the third gas discharge line 603 may be connected to the gas outflow path 27 when the third valve 66 is opened.

In addition, the gas supply line 604 may be connected to or separated from the space S through the gas inflow path 26 as the fourth valve 67 is opened or closed. For example, the gas supply line 604 may be connected to the gas inflow path 26 when the fourth valve 67 is opened.

In the step of forming the inside of the chamber 10 in the vacuum state in advance to deposit the deposition material, the first and second valves 64 and 65 may be opened to form the space S and the chamber 10 in the vacuum state. In this case, the third valve 66 and the fourth valve 67 may be in the closed state.

When the first valve 64 and the second valve 65 are opened, the air in the chamber 10 may be discharged to the outside of the chamber 10 through the first gas discharge line 601 and the second gas discharge line 602.

In detail, when the first valve 64 is opened, the first gas discharge line 601 may be connected to the gas inflow path 26.

Therefore, the first gas discharge line 601 is connected to the space S through the gas inflow path 26, such that the space S may be connected to the internal space of the chamber 10.

In this case, the air in the chamber 10 may be discharged to the outside of the chamber 10 through the first gas discharge line 601, and the air in the space S may also be discharged to the outside through the gas inflow path 26.

In addition, when the second valve 65 is opened, the second gas discharge line 602 may be connected to the pump 61, and the air in the chamber 10 may be discharged to the outside of the chamber 10 through the second gas discharge line 602.

Since the space S and the internal space of the chamber 10 are connected to each other as described above, both the space S and the internal space of the chamber 10 may be formed in the vacuum state without precise pumping control, which makes it possible to prevent damage to the substrate 2 caused by a difference in pressure between the space S and the inside of the chamber 10.

When the chamber 10 and the space S become into the vacuum state according to the step, the internal space of the chamber 10 and the space S may be separated from each other so that the backside cooling is applied.

After the chamber 10 and the space S become into the vacuum state, the first valve 64 and the second valve 65 may be closed and the third valve 66 and the fourth valve 67 may be opened during the process of depositing the scintillator.

In this case, the first gas discharge line 601 may be separated from the space S, and the second gas discharge line 602 may be separated from the pump 61.

Therefore, the internal space of the chamber 10 and the space S may be separated from each other.

The heat transfer by convection using gas needs to meet a particular condition. In this case, a pressure of the gas may be equal to or higher than a particular pressure value so that a viscous flow may be produced. In addition, even though the viscous flow is produced, heat transfer efficiency varies depending on the type of gas to be used.

As described above, in the present invention, the gas to be supplied to the space S may particularly be helium. According to the periodic table, helium is smaller in mass next to hydrogen, has almost no reactivity, and has a fine particle. Helium has best heat transfer efficiency.

Since helium has a very fine particle, helium may leak to the outside even through a very small gap. The gap may be a gap between the first fixing unit 52 and the substrate 2. It is difficult to engineeringly control the leak of helium through the gap. However, the influence of the leak of helium through the gap may be minimized by allowing helium to leak in a particular artificial method.

To allow helium to leak in a particular artificial method as described above, the pump 61 may be connected to the space S and consistently perform pumping, as illustrated in FIG. 12.

For example, the pump 61 may be a roughing pump, a speed at which the pump 61 performs the pumping on the space S may be kept constant.

Therefore, it is possible to minimize the influence of an irregular leak of helium through the gap by allowing helium to leak at a predetermined pumping speed from the space S by the pumping operation of the pump 61.

In the state in which the third valve 66 and the fourth valve 67 are opened, the pump 61 may be connected to the space S, and the gas supply source 62 and the pressure controller 63 may also be connected to the space S.

In detail, when the third valve 66 is opened, the third gas discharge line 603 may be connected to the gas outflow path 27. In this case, the third gas discharge line 603 may be connected to the space S through the gas outflow path 27.

Therefore, the pump 61 may be connected to the space S. In this case, the pump 61 is in a state of being capable of performing pumping on the space S.

When the fourth valve 67 is opened, the gas supply line 604 may be connected to the gas inflow path 26. In this case, the gas supply line 604 may be connected to the space S through the gas inflow path 26.

Therefore, the gas supply source 62 and the pressure controller 63 may be connected to the space S, and the pressure controller 63 is in a state of being capable of adjusting a pressure of the gas which is discharged from the gas supply source 62 and supplied to the space S.

After the pressure of the gas discharged from the gas supply source 62 is adjusted by the pressure controller 63, the gas may be supplied to the space S through the gas supply hole 524 via the gas inflow path 26.

In addition, the gas in the space S may be discharged to the outside through the gas outflow path 27 via the gas discharge hole 525 by the pumping operation of the pump 61.

In the state in which the internal space of the chamber 10 and the space S are separated from each other and the pump 61 performs pumping on the space S at a predetermined pumping speed (a constant pumping speed is maintained), the pressure controller 63 may read out a value of a pressure in the space S and adjust a pressure of the gas (helium) which is discharged from the gas supply source 62 and supplied to the space S. Therefore, the pressure in the space S may be kept constant during the process of depositing the scintillator.

Meanwhile, helium is inert gas having a very small particle size as described above. Even though helium is supplied to the space S, an internal pressure formed by the supplied helium may be almost equal to a vacuum pressure (a pressure range of helium is 0.01 Torr to 100 Torr).

Therefore, in the present invention, the configuration in which the sealing member O is in surface contact with the substrate 2 is used, and the gas inflow/outflow control part 60 is used, as described above. Therefore, it is possible to minimize a difference in pressure between the space S and the internal space of the chamber 10 in the vacuum state, and as a result, the substrate 2 is not damaged during the process of depositing the scintillator.

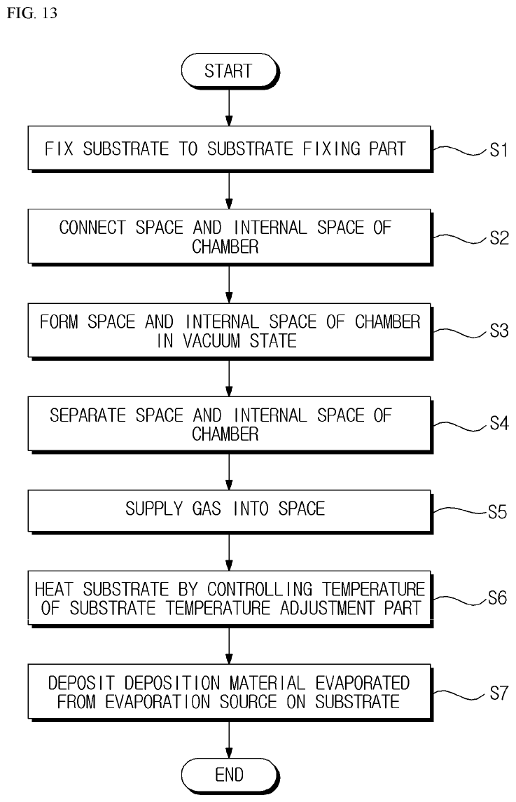

FIG. 13 is a flowchart illustrating a method of depositing a deposition material by using the substrate deposition apparatus 100 or 200 according to the present invention. Because the detailed configurations for implementing respective steps of the deposition method are disclosed in the descriptions of the substrate deposition apparatuses 100 and 200 described with reference to FIGS. 1 to 12, a detailed description thereof will be omitted.

The method of depositing a deposition material by using the substrate deposition apparatus 100 or 200 will be described with reference to FIG. 13.

First, the substrate 2 is fixed to the substrate fixing part 50 provided in the substrate deposition apparatus 100 or 200 (step S1).

Next, the space S and the internal space of the chamber 10 are connected to each other (step S2).

After the space S and the internal space of the chamber 10 are connected to each other, the space S and the internal space of the chamber 10 are formed in a vacuum state (step S3).

Next, the space S and the internal space of the chamber 10 are separated from each other to apply the backside cooling in the process of depositing a deposition material (step S4). In this case, the pumping is performed on the space S at a predetermined pumping speed by the pumping operation of the pump 61.

The gas is supplied into the space S in the state in which the space S and the internal space of the chamber 10 are separated from each other (step S5).

In this case, a value of the pressure in the space S is read out, and a pressure of the gas to be supplied into the space S is adjusted. This operation is implemented by the pressure controller 63 as described above.

Thereafter, the substrate is heated by controlling a temperature of the substrate temperature adjustment part 40 coupled to the substrate fixing part 50 (step S6), and the deposition material evaporated from the evaporation source 1 is deposited on the substrate 2 (step S7).

The above description is simply given for illustratively describing the technical spirit of the present invention, and those skilled in the art to which the present invention pertains will appreciate that various modifications, changes, and substitutions are possible without departing from the essential characteristic of the present invention. Accordingly, the embodiments disclosed in the present invention and the accompanying drawings are intended not to limit but to describe the technical spirit of the present invention, and the scope of the technical spirit of the present invention is not limited by the embodiments and the accompanying drawings. The protective scope of the present invention should be construed based on the following claims, and all the technical spirit in the equivalent scope thereto should be construed as falling within the scope of the present invention.

1. A substrate fixing device, which is configured to fix a substrate so that a deposition material evaporated from at least one evaporation source is deposited on the substrate, the substrate fixing device comprising:
a substrate temperature adjustment part configured to transfer heat to the substrate; and
a substrate fixing part coupled to one side of the substrate temperature adjustment part and configured to fix the substrate,
wherein the substrate fixing part fixes the substrate so that a front surface of the substrate is exposed in a direction toward the evaporation source, and
wherein a space is formed between the substrate fixing part and a rear surface of the substrate.

2. The substrate fixing device of claim 1, wherein the substrate temperature adjustment part comprises:
a first substrate temperature adjustment unit;
an oil flow unit provided in the first substrate temperature adjustment unit and comprising a flow path in which oil introduced from an oil supply source circulates; and
a second substrate temperature adjustment unit coupled to one side of the first substrate temperature adjustment unit.

3. The substrate fixing device of claim 2, wherein the flow path comprises:
an oil inflow line into which the oil is introduced; and
an oil outflow line from which the oil is discharged, and
wherein the oil inflow line and the oil outflow line are disposed to intersect each other.

4. The substrate fixing device of claim 2, wherein the substrate fixing part comprises:
a first fixing unit having one side to which the second substrate temperature adjustment unit is coupled; and
a second fixing unit coupled to the other side of the first fixing unit and formed such that the front surface of the substrate is exposed, and
wherein the substrate is fixed between the first fixing unit and the second fixing unit.

5. The substrate fixing device of claim 4, wherein the first fixing unit comprises:
a groove portion formed along an inner periphery of the first fixing unit;
a sealing member accommodation portion spaced apart from the groove portion at a predetermined interval, disposed inside the groove portion, formed along the inner periphery of the first fixing unit, and configured to accommodate at least one sealing member;
at least one guide pin formed between the groove portion and the sealing member accommodation portion and configured to guide the substrate when the substrate is seated on the first fixing unit;
a gas supply hole through which gas is injected into the space; and
a gas discharge hole through which the gas is discharged from the space.

6. (canceled)

7. The substrate fixing device of claim 5, wherein an edge portion is defined on the substrate and has a predetermined area along an outer edge portion of the substrate, and the edge portion is disposed between the second fixing unit and the sealing member and configured to apply stress to the sealing member.

8. The substrate fixing device of claim 4, wherein the second fixing unit comprises:
a rim portion formed on an inner peripheral surface of the second fixing unit; and
a mask area formed at an end of the rim portion, and
wherein the mask area is formed to be inclined with respect to a lower surface of the rim portion in a direction toward a central portion of the second fixing unit.

9. (canceled)

10. The substrate fixing device of claim 1, wherein the substrate fixing device is coupled to a rotation shaft of a rotation part partially accommodated in a chamber having the evaporation source therein, and the substrate fixing device rotates in conjunction with a rotation of the rotation shaft.

11. (canceled)

12. A substrate deposition apparatus, which is configured to deposit a deposition material evaporated from at least one evaporation source on a substrate, the substrate deposition apparatus comprising:
a chamber configured to accommodate the evaporation source therein;
a revolution part partially accommodated in the chamber and configured to rotate about a revolution shaft;
a plurality of rotation parts coupled to the revolution part and configured to revolve in conjunction with a rotation of the revolution part; and
a substrate fixing device according to claim 1, wherein the substrate fixing device is coupled to a rotation shaft provided in the rotation part and configured to rotate.

13. The substrate deposition apparatus of claim 12, wherein a gas inflow/outflow control part is connected to the chamber and a substrate fixing part provided in the substrate fixing device, and a space is formed between the substrate fixing part and a rear surface of the substrate.

14. The substrate deposition apparatus of claim 13, wherein after the space and the chamber are formed in a vacuum state, the gas inflow/outflow control part injects gas into the space while adjusting a pressure of the gas so that a predetermined pressure is maintained in the space during a deposition process.

15. The substrate deposition apparatus of claim 13, wherein the gas inflow/outflow control part comprises:
a pump configured to perform pumping on the space at a predetermined pumping speed;
a gas supply source configured to accommodate gas to be supplied into the space; and
a pressure controller connected to the gas supply source and configured to adjust a pressure of the gas to be supplied into the space.

16. The substrate deposition apparatus of claim 15, wherein in a state in which the pump performs pumping on the space at a predetermined pumping speed, the pressure controller adjusts a pressure of the gas to be supplied into the space by reading out a value of a pressure in the space.

17. The substrate deposition apparatus of claim 15, wherein the gas inflow/outflow control part further comprises:
a first valve disposed between the chamber and the space;
a second valve disposed between the chamber and the pump;
a third valve disposed between the pump and the space; and
a fourth valve disposed between the space and the pressure controller.

18. The substrate deposition apparatus of claim 17, wherein the first valve and the second valve are opened when the space and the chamber becomes in a vacuum state, and
wherein during the deposition process, the first valve and the second valve are closed, and the third valve and the fourth valve are opened.

19. (canceled)

20. The substrate deposition apparatus of claim 12, wherein the revolution part comprises a revolution part frame to which the plurality of rotation parts is coupled, the revolution shaft is coupled to a central portion of the revolution part frame, and the revolution part frame rotates in conjunction with a rotation of the revolution shaft.

21. The substrate deposition apparatus of claim 20, wherein the rotation part is coupled to the revolution part frame by means of a tilting shaft, and the rotation part independently and axially rotates about the tilting shaft relative to the revolution part frame.

22. (canceled)

23. A method of depositing a deposition material by using the substrate deposition apparatus according to claim 12, the method comprising:
fixing a substrate to a substrate fixing part provided in the substrate deposition apparatus;
connecting a space and an internal space of the chamber;
forming the space and the internal space of the chamber in a vacuum state;
separating the space and the internal space of the chamber;
supplying gas into the space;
heating the substrate by controlling a temperature of a substrate temperature adjustment part coupled to the substrate fixing part; and
depositing the deposition material evaporated from a plurality of evaporation sources on the substrate.

24. The method of claim 23, further comprising:
performing pumping on the space at a predetermined pumping speed in the state in which the space and the internal space of the chamber are separated from each other.

25. The method of claim 23, wherein the supplying of the gas into the space comprises adjusting a pressure of the gas to be supplied into the space by reading out a value of a pressure in the space.
